(19) United States
(12) Patent Application Publication
(10) Pub. No.: US 2026/0082917 A1
(43) Pub. Date: Mar. 19, 2026

(54) INTEGRATION OF SELF-ASSEMBLY FEATURES WITH PHOTONIC CIRCUITS

(71) Applicant: Intel Corporation, Santa Clara, CA (US)

(72) Inventors: Feras Eid, Chandler, AZ (US); Charles El Helou, Scottsdale, AZ (US); Henning Braunisch, Phoenix, AZ (US); Adel Elsherbini, Chandler, AZ (US); Brandon Rawlings, Chandler, AZ (US); Georgios Dogiamis, Chandler, AZ (US)

(73) Assignee: Intel Corporation, Santa Clara, CA (US)

(21) Appl. No.: 18/889,169

(22) Filed: Sep. 18, 2024

(51) Int. Cl. H01L 23/00; G02B 6/42; H01L 23/498; H01L 25/16

(52) U.S. Cl. CPC H10W 42/00; G02B 6/4284; H10W 90/00; H10W 90/701; H10W 72/01308; H10W 72/01333; H10W 90/724; H10W 90/734

(57) ABSTRACT

Photonics integrated circuit (PIC) dies bonded to photonics substrates, related apparatuses, systems, and methods of fabrication are disclosed. A photonics substrate and a PIC die include corresponding optical bonding regions one or both of which are surrounded by hydrophobic structures. A liquid droplet is applied to the PIC die or photonics substrate optical bonding region and the PIC die is placed on the optical bonding region of the photonics substrate. Capillary forces cause the PIC die to self-align to the optical bonding region, and an optical bond is formed by evaporating the liquid and subsequent anneal.

### BACKGROUND

Photonic integrated circuits are increasingly important in high-performance computing, data center, and cloud computing applications. Currently, photonic circuits are coupled to external waveguides with challenging submicron precision using kinematic alignment features, which add cost and processing complexity. An example deployment of kinematic alignment features is placing optical fibers into V-grooves on a silicon photonics die and affixing the fibers using an adhesive. This results in slow assembly throughput and a “pigtail” configuration that is difficult to handle in high volume, especially for arrays of fibers. Alternatively, cavities in the shape of inverted, truncated pyramids may be etched into a silicon photonics die with the appropriate crystal orientation. Precision spheres, such as sapphire spheres, may be placed into the cavities which are mated up with similar cavities on another substrate to provide the coupling. This is known as “ball in pit” coupling. However, this approach places fundamental constraints on the silicon photonics die such as its crystal orientation and assembly processing, which is difficult to implement in high volume using standardized tools.

Difficulties in packaging and coupling photonic circuits to other devices persist. It is with respect to these and other considerations that the present improvements have been needed. Such improvements may become critical as the desire to deploy high-performance photonic circuits in integrated circuit devices, packages, and systems becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A is an illustration of a cross-sectional side view of a PIC structure being bonded to a photonics coupler structure using self-alignment assembly features;

FIG. 1B is an illustration of a cross-sectional side view of a photonics structure after bonding the PIC structure and the photonics coupler structure of FIG. 1A;

FIG. 2 is a flow diagram illustrating example methods for fabricating PIC structures inclusive of a PIC die bonded to an intermediate photonic coupler;

FIGS. 3A, 3B, 3C, 3D, 3E, 4A, 4B, 4C, 4D, and 4E are illustrations of cross-sectional side views of PIC structures and/or intermediate photonic coupler structures being prepared for self-alignment bonding;

FIG. 5A is an illustration of a cross-sectional side view of a PIC structure being bonded to a photonics coupler structure larger than the PIC structure such that both have rectangular optical bonding regions;

FIG. 5B is an illustration of plan views of the PIC structure and the photonics coupler structure of FIG. 5A;

FIG. 5C is an illustration of a cross-sectional side view of a photonics structure after bonding the PIC structure and the photonics coupler structure of FIGS. 5A and 5B;

FIG. 6A is an illustration of a cross-sectional side view of a PIC structure being bonded to a photonics coupler structure of substantially the same size of the PIC structure such that both have square within cross optical bonding regions;

FIG. 6B is an illustration of plan views of the PIC structure and the photonics coupler structure of FIG. 6A;

FIG. 6C is an illustration of a cross-sectional side view of a photonics structure after bonding the PIC structure and the photonics coupler structure of FIGS. 6A and 6B;

FIG. 7A is an illustration of a cross-sectional side view of a PIC structure being bonded to a photonics coupler structure of substantially the same size of PIC structure such that both have multiple optical bonding regions;

FIG. 7B is an illustration of plan views of the PIC structure and the photonics coupler structure of FIG. 7A;

FIG. 7C is an illustration of a cross-sectional side view of a photonics structure after bonding the PIC structure and the photonics coupler structure of FIGS. 7A and 7B;

FIG. 8A is an illustration of a cross-sectional side view of a PIC structure being bonded to a photonics coupler structure larger than the PIC structure and having a non-optical bonding region;

FIG. 8B is an illustration of plan views of the PIC structure and the photonics coupler structure of FIG. 8A;

FIG. 8C is an illustration of a cross-sectional side view of a photonics structure after bonding the PIC structure and the photonics coupler structure of FIGS. 8A and 8B;

FIG. 9 is an illustration of a cross-sectional side view of an assembly structure similar to the photonics structure of FIG. 6C after attachment to an external optical fiber array connector, packaging with an electronic IC die;

FIG. 10 illustrates an exemplary system employing a self-alignment bonded photonics integrated circuit and photonics coupler; and

FIG. 11 is a block diagram of a computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. Herein, the term “predominantly” indicates not less than 50% of a particular material or component while the term “substantially pure” indicates not less than 99% of the particular material or component and the term “pure” indicates not less than 99.9% of the particular material or component. Unless otherwise indicated, such material percentages are based on atomic percentage. Herein the term concentration is used interchangeably with material percentage and also indicates atomic percentage unless otherwise indicated.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on”a second layer is in direct contact with that second layer. Similarly, unless explicitly stated otherwise, one feature disposed between two features may be in direct contact with the adjacent features or may have one or more intervening features. The term immediately adjacent indicates such features are in direction contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Photonics integrated circuit structures, hybrid devices, apparatuses, systems, and methods are described herein related to integrating photonics integrated circuits using self-assembly features.

As described above, photonic integrated circuits (PICs) such as PIC dies may be coupled to external waveguides or other photonics devices. The precision of such coupling is critical with submicron precision typically being required. In some embodiments, self-assembly features are deployed to couple a PIC die to an intermediate photonic coupler, such as a substrate having optical features, with high precision. The intermediate photonic coupler can then be coupled to an external photonics device such as an external optical fiber array connector using standard alignment pins and pin holes. Such techniques and structures offer the advantages of an efficient architecture and process and fast throughput by eliminating the need for precision alignment bonders or similar tools.

In some embodiments, the self-assembly features are hydrophobic features that surround optical coupling regions of one or both of the PIC die and the intermediate photonic coupler or substrate. These features may be characterized as liquid confinement features since the hydrophobic features provide containment for a liquid droplet. As discussed further herein, the hydrophobic features may be hydrophobic materials or hydrophobic structures such as edges or a roughened surface or both hydrophobic materials and hydrophobic structures. Notably, the hydrophobic features on one or both of the PIC or intermediate coupler are aligned to corresponding waveguides on each surface via wafer, panel, or die-level processes. That is, the hydrophobic features are placed with high accuracy relative to the photonics or optical features within the corresponding optical coupling regions. Accurate alignment of the hydrophobic features between the PIC die and the intermediate photonic coupler then provides accurate alignment of photonics or optical features within the corresponding optical coupling regions to be coupled to one another.

A liquid droplet is dispensed on the bonding area (i.e., optical coupling region) on either the PIC or intermediate coupler. As discussed, the liquid droplet is contained within the bonding area due to the hydrophobic features. Then, a fast bonder is used to pick and place the PIC die onto the intermediate coupler (or vice versa) at coarse alignment (e.g., about 25 to 50 um), such that the water droplet is sandwiched in the bonding area between the two. Notably, the pick and place operations at such coarse alignment can be performed quickly. Capillary forces cause the confinement features on each surface to self-align to those on the other with high positional accuracy (e.g. <200 nm) due to the liquid confinement features (e.g., hydrophobic features) discussed above. Since those features are also already aligned to the optical features (e.g., waveguides) on each surface, this ensures the optical features to be coupled (e.g., waveguides) on both surfaces are aligned to each other with the same positional accuracy. The liquid then evaporates, leaving the two surfaces bonding. Finally, an annealing step may be carried out to form and/or strengthen bonds between the two surfaces. The bonding may be fusion bonding, hybrid bonding, or similar.

As used herein, the term PIC die includes any monolithic photonics integrated device that provides optical functionality. The term optical substrate, substrate, intermediate photonic coupler, or the like indicates a substrate having active or passive photonics or optical features. In the context of bonding of PIC dies, faster throughput may be attained using the discussed self-alignment assisted assembly.

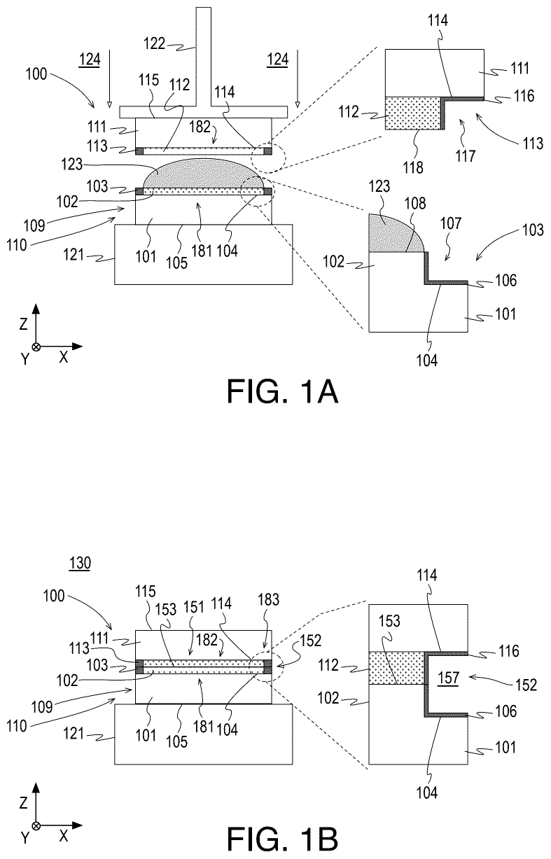

FIG. 1A is an illustration of a cross-sectional side view of a PIC structure 100 being bonded to a photonics coupler structure 110 using self-alignment assembly features, arranged in accordance with at least some implementations of the present disclosure. As shown in FIG. 1A, a liquid droplet 123 is deposited on an optical coupling layer 102 of photonics coupler structure 110 within an optical bonding region 181. Liquid droplet 123 is contained within the area of optical bonding region 181 of optical coupling layer 102 by hydrophobic features or structures 103 which fully or substantially surround optical bonding region 181 of optical coupling layer 102. For example, hydrophobic features or structures 103 are adjacent an outer perimeter of bonding region 181. As used herein, the term optical coupling layer indicates a layer including one or more optical devices or structures that are to be coupled to corresponding optical devices or structures of another device. For example, the optical devices or structures may be optical waveguides, optical bond pads, or the like.

Optical coupling layer 102 of photonics coupler structure 110 is on or over a surface 104 of optical substrate 101 such that surface 104 is opposite the body of optical substrate 101 with respect to a backside surface 105. Optical substrate 101 may be mounted to a work surface such as a chuck 121. Optical coupling layer 102 may be a layer formed on or over optical substrate 101 or optical coupling layer 102 may be integral with optical substrate 101 (i.e., optical coupling layer 102 and optical substrate 101 may be part of the same monolithic structure). Optical substrate 101 may be any suitable substrate material and structure and, in some embodiments, optical substrate 101 may be characterized as a substrate or a base substate.

In some embodiments, optical substrate 101 is a glass core substrate with optical waveguides formed therein such that the optical waveguides extend in the x-y plane. In some embodiments, optical coupling to PIC structure 100 provides an optical routing from PIC structure 100, through a coupling with optical coupling layer 102, into a body of optical substrate 101 and extending out of optical substrate 101 at a sidewall 109 thereof. Such coupling is discussed further herein with respect to FIG. 9.

Optical substrate 101 may be any appropriate structure, including, but not limited to, an intermediate photonics coupler. Optical substrate 101 may include a glass substrate body, which may be characterized as a layer of glass, and any number of optical waveguides or similar optical features formed on or within optical substrate 101 using techniques known in the art. Although discussed herein with respect to optical waveguides, optical substrate 101 may include any optical features or couplers.

Optical substrate 101, which may also be characterized as a glass substrate, may have any suitable characteristics. In some embodiments, optical substrate 101 includes a layer of glass (e.g., a glass core). In some embodiments, the layer of glass of optical substrate 101 is an amorphous solid glass layer. In some embodiments, glass optical substrate 101 includes a layer of glass, which, for example, is one of aluminosilicate, borosilicate, alumino-borosilicate, silica, and fused silica. The layer of glass may include one or more of additives including Al₂O₃, B₂O₃, MgO, CaO, SrO, BaO, SnO₂, Na₂O, K₂O, P₂O₃, ZrO₂, Li₂O, Ti, or Zn. For example, the layer of glass may include an additive including one or more of aluminum, boron, magnesium, calcium, strontium, barium, tin, sodium, potassium, phosphorous, zirconium, lithium, titanium, or zinc. In some embodiments, the layer of glass may include silicon and oxygen and one or more of aluminum, boron, magnesium, calcium, strontium, barium, tin, sodium, potassium, phosphorous, zirconium, lithium, titanium, and zinc. In some embodiments, the layer of glass includes at least 23 percent silicon and at least 26 percent oxygen by weight, and further includes at least 5 percent aluminum by weight. In some embodiments, the layer of glass is rectangular in shape in plan view. However, other shapes may be used. In some embodiments, the layer of glass of optical substrate 101 is absent any organic adhesive or other organic material.

In some embodiments, the layer of glass of optical substrate 101 has a thickness in the range of 50 microns to 1.4 mm (i.e., in the z-dimension). In some embodiments, optical substrate includes a multi-layer glass substrate (e.g., a coreless substrate) where a glass layer of glass substrate 101 has a thickness in the range of about 25 microns to 50 microns. In some embodiments, glass substrate has a first length L1 and a second length L2 (or a width) in the x-y plane. In some embodiments, first length L1 is in the range of about 10 mm to 250 mm and second length L2 is in the range of about 10 mm to 250 mm. For example, glass optical substrate 101 may have dimensions in the range of about 10 mm×10 mm to 250 mm×250 mm. Other lateral lengths and thicknesses may be used. In some embodiments, a glass core or a glass layer of optical substrate 101 is a rectangular prism volume with sections removed and filled with other materials to form optical features. In some embodiments, optical substrate 101 includes a layer of glass having a thickness of not less than 50 microns (in the z-dimension), a first length of not less than 10 mm and a second length orthogonal to the first length of not less than 10 mm (in the x-y plane), and an optical waveguide within the layer of glass, such that the optical waveguide extends substantially orthogonal to the thickness of the layer of glass (i.e., the optical waveguide extends in the x-y plane).

As discussed, liquid droplet 123 on a surface 108 of optical coupling layer 102 is contained within optical bonding region 181 of optical coupling layer 102 by hydrophobic features or structures 103 which fully or substantially surround the area of optical coupling layer 102. Hydrophobic features or structures 103 may be characterized as liquid containment features and may include any materials or structures discussed herein, such as a hydrophobic coating or hydrophobic materials 106 and/or a stepped edge 107, as illustrated in the enlarged view. Additional exemplary hydrophobic features or structures 103 are discussed herein below. As also shown in the enlarged view of optical substrate 101, optical coupling layer 102 may be integral to the body of optical substrate 101 in some embodiments.

As shown, PIC structure 100 includes an optical coupling layer 112, which may have corresponding optical features to couple with those of optical coupling layer 102. For example, optical features may be distributed in a field material in both of optical coupling layers 102, 112 and it is desired to perfectly couple mirrored patterns of the optical features and field material in a one-to-one manner. Optical coupling layer 112 of PIC structure 100 is on or over a surface 114 of PIC structure 100, which is opposite the body of PIC structure 100 with respect to a backside surface 115. As with optical coupling layer 102, optical coupling layer 112 may be a layer formed on or over PIC die 111 or optical coupling layer 112 may be integral with PIC die 111. PIC die 111 may be any suitable substrate material and structure and, in some embodiments, PIC die 111 may be characterized as a PIC device, PIC chiplet, or the like.

In some embodiments, PIC die 111 is a PIC or integrated optical circuit having two or more photonic components that form a functioning circuit such that PIC die 111 detects, generates, transports, and processes light. PIC die 111 may include any functional blocks or units. PIC die 111 may be any suitable material such as silicon although other material systems may be used. As shown, hydrophobic features or structures 113 surround an area of an optical bonding region 182 of optical coupling layer 112. For example, hydrophobic features or structures 113 are adjacent an outer perimeter of bonding region 182. Hydrophobic features or structures 113 may be characterized as liquid containment features and may include any materials or structures discussed herein, such as a hydrophobic coating or hydrophobic materials 116 and/or a stepped edge 117, as illustrated in the enlarged view. Additional exemplary hydrophobic features or structures 113 are discussed herein below. In some embodiments, stepped edges 107, 117 may be defined and patterned using lithography and etch techniques. Notably, such techniques provide for highly accurate placement of hydrophobic features or structures 103, 113 relative to optical bonding features of optical coupling layers 102, 112.

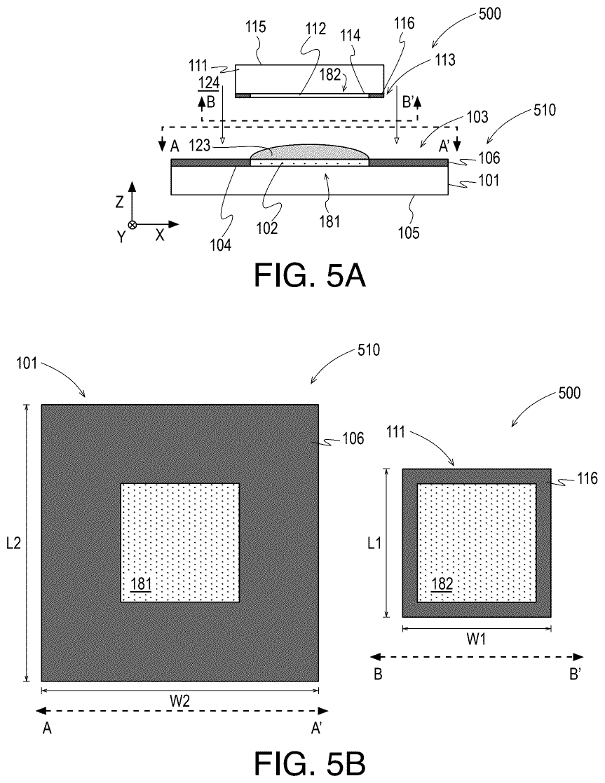

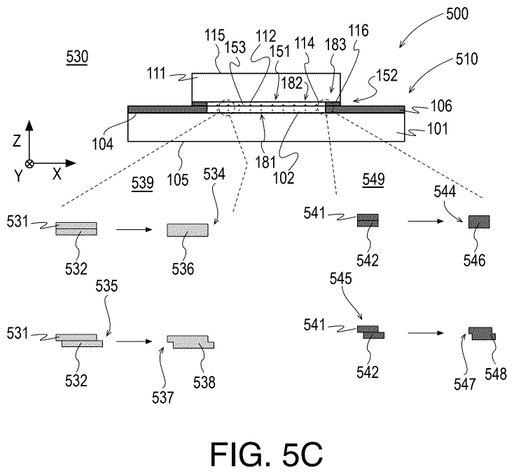

As shown, PIC structure 100 may be held by a bonder 122 and PIC structure 100 is coarsely aligned with photonics coupler structure 110 and placed using placement operation 124 on liquid droplet 123. As shown, surface 118 of optical coupling layer 112 is placed directly on liquid droplet 123 and released. In the context of placement operation 124, the processing may be die-to-wafer placement, die-to-panel placement, panel-to-panel placement, or the like. Notably, segmentation operations such as dicing may be performed after bonding PIC structure 100 and photonics coupler structure 110. As discussed, liquid droplet is dispensed on optical coupling layer 102 and a fast-bonding tool including bonder 122 may be used to pick and place PIC structure 100 onto photonics coupler structure 110 (or vice versa) at coarse alignment (e.g., about 25 to 50 um). After placement operation 124, liquid droplet is sandwiched between the bonding areas of optical coupling layers 102, 112. Capillary forces cause hydrophobic features or structures 103, 113 (i.e., confinement features) and therefore optical coupling features of each optical coupling layers 102, 112 to self-align with each other with high positional accuracy (e.g., not more than 200 nm) due to hydrophobic features or structures 103, 113. Such alignment may be characterized as passive alignment due to the nature of the tool placement being complete prior to further alignment of the features. Since hydrophobic features or structures 103, 113 are also already aligned with high accuracy to the optical features (e.g., waveguides) being bonded on each surface; this ensures the optical features (e.g., waveguides) on both surfaces are aligned to each other with the same positional accuracy. Liquid droplet 123 then evaporates, leaving surfaces 108, 118 of optical coupling layers 102, 112 to bond. As discussed herein below with respect to FIG. 5C, optical features of optical coupling layer 102 are thereby accurately aligned to optical features of optical coupling layer 112. An anneal operation may be carried out to form and/or strengthen bonds between optical coupling layers 102, 112. The bonding may be fusion bonding, hybrid bonding, or the like. In some embodiments, like materials of optical features of optical coupling layer 102, 112 are bonded with one another as are like materials of a field material of each of optical coupling layer 102, 112. In some embodiments, additional metal features are included to form a hybrid bond.

FIG. 1B is an illustration of a cross-sectional side view of a photonics structure 130 after bonding PIC structure 100 and photonics coupler structure 110, arranged in accordance with at least some implementations of the present disclosure. As shown, a bond 151 is formed between surfaces 108, 118 of optical coupling layers 102, 112 at an interface 153 therebetween such that optical bonding regions 181, 182 are aligned and adjoined. As discussed, interface 153 may include interfaces between optical features or structures interspersed among interfaces between field materials such as a field dielectric with between optical features or structures being aligned to high accuracy. Such bonded optical features or structures may be characterized as single features or as bonded features. In a similar manner, a bond 152 may be formed between hydrophobic materials 106, 116 when such materials are employed. Furthermore, stepped edges 107, 117 may form a concave region 157 around bonded optical coupling layers 102, 112 when stepped edges 107, 117 are employed.

After bonding, photonics structure 130 includes optical coupling layer 102 over surface 104 of optical substrate 101 such that optical coupling layer 102 is within optical bonding region 181 of surface 104 of optical substrate 101. Photonics structure 130 further includes optical coupling layer 112 over surface 114 of PIC die 111 (which may be characterized as a PIC substrate) such that optical coupling layer 112 is within matching optical bonding region 182 of surface 114 of PIC die 111. As shown, optical coupling layer 102 is coupled to optical coupling layer 112 at interface 153 via bond 151. Photonics structure 130 includes one or more hydrophobic structures 103, 113 extending substantially around an outer perimeter 183 of optical coupling layers 102, 112 such that hydrophobic structures 103, 113 are each between surface 104 of optical substrate 101 and surface 114 of a PIC die 111.

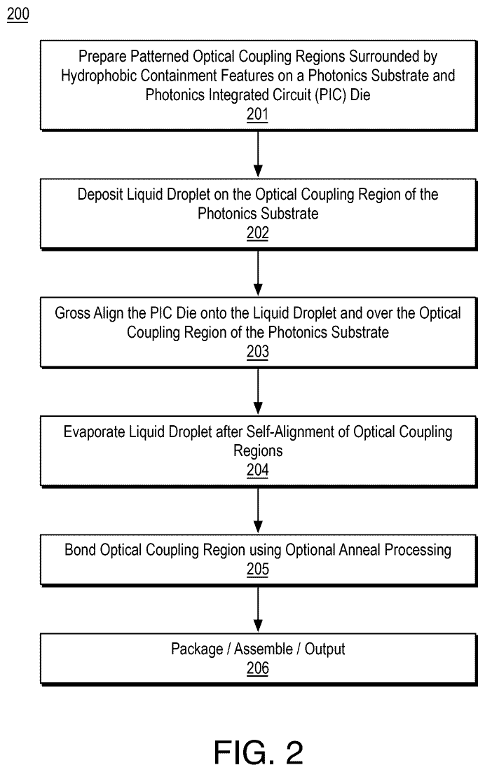

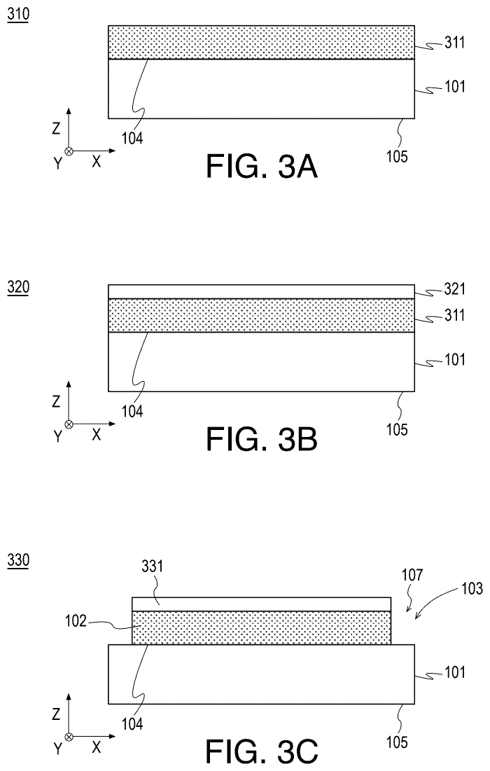

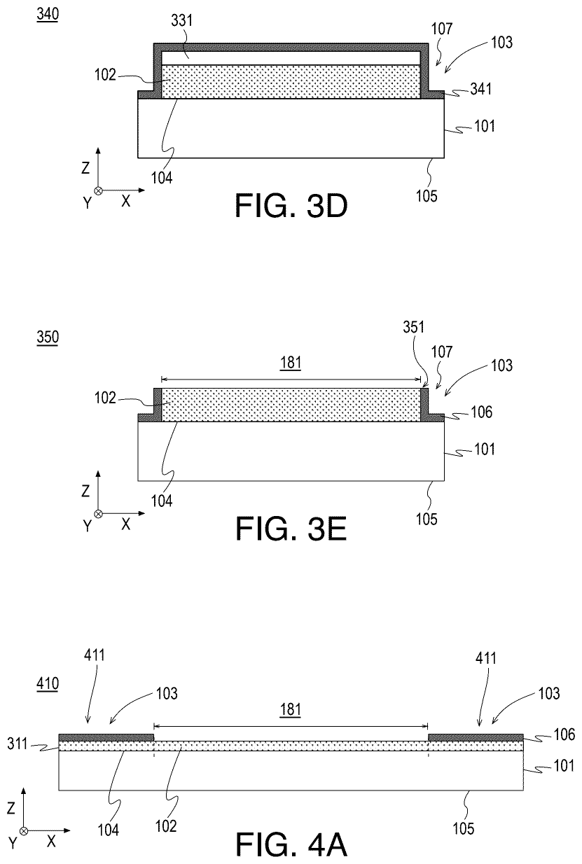

FIG. 2 is a flow diagram illustrating example methods 200 for fabricating PIC structures inclusive of a PIC die bonded to an intermediate photonic coupler, arranged in accordance with at least some implementations of the present disclosure. For example, methods 200 may be implemented to fabricate photonics structures 130, 530, 630, 730, 830, assembly structure 900, or any other structure discussed herein. In the illustrated embodiment, methods 200 include one or more operations as illustrated by operations 201 -206 . However, embodiments herein may include additional operations, certain operations being omitted, or operations being performed out of the order provided. FIGS. 3A, 3B, 3C, 3D, 3E, 4A, 4B, 4C, 4D, 4E, 5A, 5B, 5C, 6A, 6B, 6C, 7A, 7B, 7C, 8A, 8B, 8C, and 9 illustrate structures and components as methods 200 are practiced.

Methods 200 begins at operation 201, where bonding areas of optical coupling layers surrounded by hydrophobic containment features are prepared on a photonics coupler structure and a PIC die. In methods 200, PIC dies are attached to a photonics substrate such as an intermediate photonics coupler. Such attachment techniques place the PIC die onto the photonics substrate quickly and with gross alignment and then use a liquid droplet between the bonding areas to provide passive fine alignment using capillary forces. Such self-alignment bonding techniques allow for high throughput as high duration pick and place alignment is not needed.

FIG. 3A is an illustration of a cross-sectional side view of a photonics structure 310 being prepared for self-alignment bonding. As shown, photonics structure 310 includes optical substrate 101 and a bulk optical layer 311 formed on optical substrate 101. As discussed, photonics structure 310 may be a structural wafer or panel or the like. Photonics structure 310 may include photonics structures or features such as waveguides or the like. Although illustrated with respect to forming hydrophobic features on or over optical substrate 101, it is understood the same or similar processes are deployed to fabricate hydrophobic features on or over PIC die 111. Such hydrophobic features are used during bonding as discussed herein. It is noted that the hydrophobic features employed between optical substrate 101 and PIC die 111 may be the same or they may be different. In some embodiments, optical layer 311 may be prepared for bonding by, for example, a chemical mechanical polishing (CMP) operation.

Optical layer 311 includes a number of optical features interspersed in a bulk material such that the optical features are to be coupled to corresponding optical features as discussed herein. Such optical features are illustrated herein with respect to FIG. 5C but are not typically illustrated elsewhere for the sake of clarity of presentation. In some embodiments, the optical features to be coupled are optical waveguides although other features may be coupled using the techniques discussed herein. In some embodiments, the optical features are a first material such as silicon oxide (e.g., includes silicon and oxygen) or silicon nitride (e.g., includes silicon and nitrogen) and the bulk material is a second material such as silicon oxide, silicon nitride, silicon oxynitride (e.g., includes silicon, oxygen, and nitrogen), silicon-carbon-nitrogen composite (e.g., includes silicon, carbon and nitrogen), silicon carbide (e.g., includes silicon and carbon), or other dielectric material. In some embodiments, the optical features are silicon nitride, and the bulk material is silicon oxide, a silicon-carbon-nitrogen composite, or other dielectric material. In some embodiments, the optical features are silicon oxide, and the bulk material is silicon-carbon-nitrogen composite or other dielectric material.

FIG. 3B illustrates a photonics structure 320 similar to photonics structure 310 after formation of a sacrificial layer 321 on optical layer 311. Sacrificial layer 321 may be any suitable material. In some embodiments, sacrificial layer 321 has an etch selectivity relative to the materials of optical layer 311. In some embodiments, sacrificial layer 321 is an organic material such as photoresist. In some embodiments, sacrificial layer 321 is an inorganic material such as aluminum oxide (i.e., includes aluminum and oxygen), aluminum nitride (i.e., includes aluminum and nitrogen), titanium nitride (i.e., includes titanium and nitrogen), or the like.

FIG. 3C illustrates a photonics structure 330 similar to photonics structure 320 after patterning optical layer 311 and sacrificial layer 321 such that the patterning of optical layer 311 forms optical coupling layer 102 and patterned sacrificial layer 331, as well as hydrophobic structure 103 inclusive of stepped edge 107. sacrificial layer 321 and optical layer 311 may be patterned using any suitable technique or techniques such as wet or dry etch processing, laser ablation or the like.

It is noted that stepped edge 107 provides for containment of a liquid droplet due to the edge of optical coupling layer 102. However, improved containment can be attained using hydrophobic materials. In some embodiments, optical coupling layer 102 may be characterized as a hydrophilic structure or layer as it allows for the liquid droplet to spread out. As discussed, optical coupling layer 102 may include one or more inorganic materials such as silicon oxide, silicon nitride, silicon oxynitride, silicon carbonitride, or silicon carbide. Such materials are hydrophilic such that a liquid (e.g., water) will spread out on optical coupling layer 102 as the liquid minimizes its surface energy. Patterned hydrophilic structures 301 therefore define optical bonding regions 181 for self-alignment.

FIG. 3D illustrates a photonics structure 340 similar to a photonics structure 330 after formation of conformal hydrophobic material layer 341 on and over patterned sacrificial layer 331 and on and over optical coupling layer 102. Conformal hydrophobic material layer 341 may be formed using any suitable technique or techniques such as spin coating, conformal vapor deposition, or the like. Conformal hydrophobic material layer 341 may be any suitable material for confining a liquid droplet (e.g., water droplet) and such materials are discussed herein below with respect to FIG. 3E.

FIG. 3E illustrates a photonics structure 350 similar to a photonics structure 340 after removal of a portion of hydrophobic material layer 341 and an entirety of patterned sacrificial layer 331 to form hydrophobic features or structures 103 which include stepped edge 107 and hydrophobic material 106 on sidewalls 351 of optical coupling layer 102. Conformal hydrophobic material layer 341 may be removed from the lateral or horizontal surfaces while remaining on sidewalls 351 using any suitable processing such as an anisotropic etch including dry etch processes.

Hydrophobic material 106 (which may be characterized as hydrophobic spacers, hydrophobic features, or the like) may include any suitable hydrophobic material (e.g., material that causes a liquid water droplet to have a contact angle of greater than 90°). In some embodiments, hydrophobic material 106 is a chemical coating or hydrophobic material that create a hydrophobic boundary with a large contact angle (e.g., >90°) around optical bonding regions 181. In some embodiments, the hydrophobic material of hydrophobic structures 103 is or includes a self-assembled monolayer (SAM) material such as an alkyl or fluoroalkyl silane (e.g., ODS, FDTS), a thiol (e.g., hexadecane thiol), a phosphonic acid (e.g., octadecyl or perfluorooctane phosphonic acid), or an alkanoic acid (e.g., heptadecanoic acid). However, non-SAM based materials or films may be used. In some embodiments, the hydrophobic material of hydrophobic structures 401 is or includes a thin polymer film such as a siloxane (e.g., PDMS and derivatives, HMDSO), a silazane (HMDS), a polyolefin (e.g., PP), or a fluorinated polymer (e.g., PTFE, PFPE, PFDA, C4F8 plasma polymerized films, etc.). Other hydrophobic materials may be used. In accordance with some embodiments of the present disclosure, hydrophobic material 106 may include a layer of material having an atomic composition of at least 10% carbon, a layer of material having an atomic composition of at least 10% fluorine, a layer of material having an atomic composition of at least 10% phosphorus, a layer of material having an atomic composition of at least 10% sulfur, and/or or a layer of material having an atomic composition of at least 10% silicon.

As discussed, hydrophobic structures 103 will contain a liquid within optical bonding regions 181 while optical coupling layer 102 allow the liquid to spread out in optical bonding regions 303. For example, optical coupling layer 102 may be inorganic materials such as silicon oxide, silicon nitride, silicon oxynitride, silicon carbonitride, or silicon carbide. Such materials are hydrophilic such that a liquid (e.g., water) will spread out as the liquid minimizes its surface energy. Hydrophobic structures 103, in contrast, will contain the liquid. Hydrophilic materials or surfaces cause a liquid droplet to have a contact angle of less than 90° (e.g., water on silicon oxide has a contact angle of ˜10-20°) while a hydrophobic structure causes a contact angle of greater than 90° in the liquid droplet. As used herein, the term hydrophobic structure is inclusive of both topological alterations (e.g., alterations to an otherwise hydrophilic structure such as a stepped edge) and hydrophobic materials.

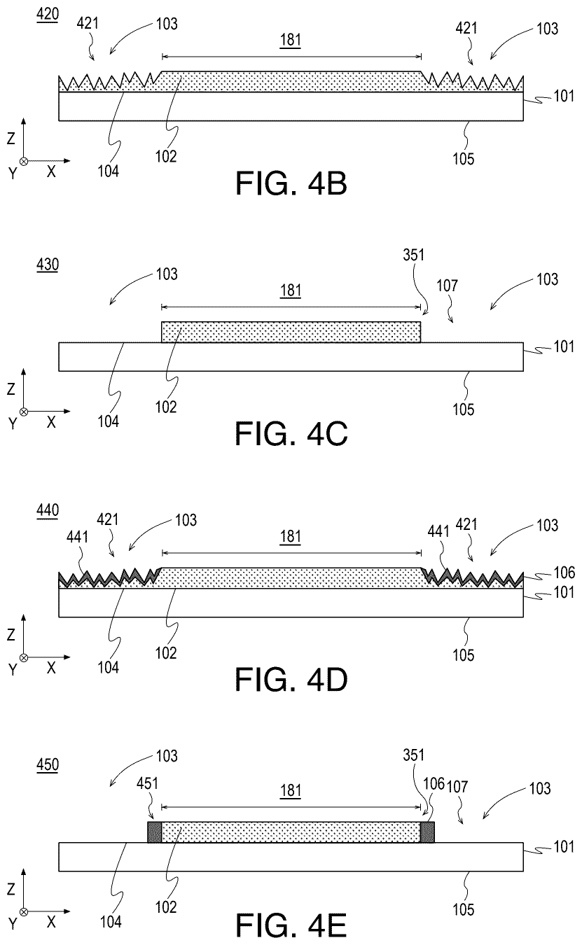

In the embodiment of FIG. 3E, optical bonding regions 181 are within hydrophobic material 106 and stepped edge 107. Notably, stepped edges and other structural changes are also hydrophobic structures or features as they contain a liquid droplet. The embodiment of FIG. 3E offers the advantages of multiple and diverse hydrophobic features (e.g., both material based and structure based hydrophobic structures). FIG. 4A-4E illustrate alternative hydrophilic structures and hydrophobic structures for the containment of a liquid within optical bonding regions 181. As discussed, hydrophobic structures 113 may be fabricated in the same or similar manner, and any features discussed with respect to hydrophobic structures 103 may be present in hydrophobic structures 113.

FIG. 4A illustrates a photonics structure 410 similar to photonics structure 310 after formation of hydrophobic structures 103, inclusive of an overlying hydrophobic patterned material layer 411 to define optical bonding region 181 as portions of optical layer 311. For example, optical bonding region 181 may define an area of optical coupling layer 102. Optical bonding region 181 of optical layer 311 may also be characterized as a hydrophilic structure. Hydrophobic patterned material layer 411, which may include any material discussed with respect to hydrophobic material 106, may be formed using any suitable technique or techniques such as forming a conformal hydrophobic material layer on bulk optical layer 311, and subsequently patterning the conformal hydrophobic material layer by patterning a resist layer on or over the hydrophobic material layer, etching the exposed portions of the hydrophobic material layer, and removing the resist layer.

Hydrophobic patterned material layer 411 may include any hydrophobic material discussed above and hydrophobic patterned material layer 411 may be deployed as hydrophobic structures 103. For example, hydrophobic patterned material layer 411 may be or include a self-assembled monolayer material such as an alkyl or fluoroalkyl silane, a thiol, a phosphonic acid, or an alkanoic acid, or hydrophobic patterned material layer 411 may be or include a polymer film such as a siloxane, a silazane, a polyolefin, or a fluorinated polymer. Other hydrophobic materials may be used. In accordance with some embodiments of the present disclosure, hydrophobic patterned material layer 411 may include a layer of material having an atomic composition of at least 10% carbon, a layer of material having an atomic composition of at least 10% fluorine, a layer of material having an atomic composition of at least 10% phosphorus, a layer of material having an atomic composition of at least 10% sulfur, and/or or a layer of material having an atomic composition of at least 10% silicon.

FIG. 4B illustrates a photonics structure 420 similar to photonics structure 310 after formation of hydrophobic structures 103 including roughened surfaces 421 for self-aligned bonding. Hydrophobic structures 103 including roughened surfaces 421 may be formed using any suitable technique or techniques such as surface texturing techniques inclusive of laser surface roughening. Roughened surfaces 421 may have any suitable surface roughness relative to the surface of optical coupling layer 102 in optical bonding regions 181. In some embodiments, the surface roughness (i.e., measured as the deviations in the direction of the normal vector of a real surface from its ideal form) of roughened surfaces 421 is not less than twice the surface roughness of the surface of optical coupling layer 102 in optical bonding regions 181. For example, a ratio of the roughnesses may be defined as the surface roughness of roughened surfaces 421 divided by the surface roughness of the surface of optical coupling layer 102 in optical bonding regions 181. In some embodiments, the ratio is not less than two. In some embodiments, the ratio is not less than five, ten, or twenty. In some embodiments, the ratio is not less than 100.

FIG. 4C illustrates a photonics structure 430 similar to photonics structure 310 after formation of hydrophobic structures 103 where stepped edge 107 are used as hydrophobic structures. Hydrophobic structures 103 including stepped edge 107 may be formed using any suitable technique or techniques such as pattering and etch processing, laser ablation processing, or the like. As discussed, the hydrophilic nature of optical bonding regions 181 causes a liquid (e.g., water) to spread out. Stepped edge 107, which may be characterized as trenches, in contrast, provide hydrophobic structures 103 that contain the liquid. In the context of FIG. 4C, sidewalls 351 and their upper corners are defined by stepped edge 107. As a liquid droplet spreads out, it interacts with the corner, which alters the surface energy characteristics of the liquid droplet and, in turn, changes the effective contact angle to greater than 90°. Thereby, the liquid droplet is contained within optical bonding region 181.

FIG. 4D illustrates a photonics structure 440 similar to photonics structure 420 after formation of hydrophobic structures 103 including a hydrophobic material coating 441 on roughened surfaces 421 for self-aligned bonding. Hydrophobic material coating 441 may be formed using any suitable technique or techniques such as forming a conformal hydrophobic material layer, and subsequently patterning the conformal hydrophobic material layer by patterning a resist layer on or over the hydrophobic material layer, etching the exposed portions of the hydrophobic material layer, and removing the resist layer. Hydrophobic material coating 441 may include any hydrophobic material discussed herein such as a self-assembled monolayer material including an alkyl or fluoroalkyl silane, a thiol, a phosphonic acid, or an alkanoic acid, or a polymer film including a siloxane, a silazane, a polyolefin, or a fluorinated polymer. Other hydrophobic materials may be used. In accordance with some embodiments of the present disclosure, hydrophobic material coating 441 may include a layer of material having an atomic composition of at least 10% carbon, a layer of material having an atomic composition of at least 10% fluorine, a layer of material having an atomic composition of at least 10% phosphorus, a layer of material having an atomic composition of at least 10% sulfur, and/or or a layer of material having an atomic composition of at least 10% silicon.

FIG. 4E illustrates a photonics structure 450 similar to photonics structure 430 after formation of hydrophobic structures 103 including a sidewall spacer of hydrophobic material 451. Hydrophobic material 451 may be formed on sidewalls 351 using any suitable technique or techniques. In some embodiments, a conformal hydrophobic material layer is formed on exposed surfaces of photonics structure 430 using, for example, spin coating or conformal vapor deposition. The conformal hydrophobic material layer is then removed from the lateral or horizontal surfaces while the conformal hydrophobic material layer remains on sidewalls 351 via an anisotropic etch such as a dry etch.

Hydrophobic material 451, which may be characterized as a hydrophobic spacer, hydrophobic feature, or the like may include any suitable hydrophobic material (e.g., material that causes a liquid water droplet to have a contact angle of greater than 90°) discussed above such as a self-assembled monolayer material including an alkyl or fluoroalkyl silane, a thiol, a phosphonic acid, or an alkanoic acid, or a polymer film including a siloxane, a silazane, a polyolefin, or a fluorinated polymer. Other hydrophobic materials may be used. In accordance with some embodiments of the present disclosure, hydrophobic material coating 441 may include a layer of material having an atomic composition of at least 10% carbon, a layer of material having an atomic composition of at least 10% fluorine, a layer of material having an atomic composition of at least 10% phosphorus, a layer of material having an atomic composition of at least 10% sulfur, and/or or a layer of material having an atomic composition of at least 10% silicon. As discussed, hydrophobic structures 113 may be fabricated in the same or similar manner, and any features discussed with respect to hydrophobic structures 103 may be present in hydrophobic structures 113.

Returning to FIG. 2, methods 200 continues at operation 202, where a liquid droplet such as a water droplet is applied to an optical coupling region of a photonics substrate such that the liquid droplet is retained within the optical coupling region by one or more hydrophobic structures surrounding the optical coupling region. Although illustrated with respect to the liquid droplet being applied to the optical coupling region of the photonics substrate, the liquid droplet may be applied to the optical coupling region of the PIC die in some embodiments.

Methods 200 continues at operation 203, where the PIC die is gross aligned onto the liquid droplet such that an optical coupling region of the PIC die is placed on the liquid droplet. The PIC die may be placed on the liquid droplet using any suitable technique or techniques such as rapid pick and place techniques or the like. Although illustrated with respect to the PIC die being placed on the liquid droplet, the photonics substrate may be placed on the liquid droplet in some embodiments.

Methods 200 continues at operation 204, where, after self-alignment of the optical coupling regions of the PIC die and the photonics substrate, the liquid droplet is evaporated. Notably, the interplay of the liquid droplet, the hydrophilic optical bonding regions, and the hydrophobic containment features cause the PIC die to self-align with high accuracy to the photonics substrate. Furthermore, the liquid droplet applied at operation 202 evaporates relatively quickly after alignment and the materials, such as inorganic materials, of the optical bonding regions hold the PIC die in place due to, for example, Van der Waals forces.

Methods 200 continues at operation 205, where a subsequent anneal operation may be performed to bond the PIC die to the photonics substrate by melding the materials therebetween. In some embodiments, the evaporation of the liquid droplet may be at room temperature although heating may be applied. The subsequent anneal may be applied at any suitable temperature such as a temperature in the range of 200 to 400° C.

FIG. 5A is an illustration of a cross-sectional side view of a PIC structure 500 being bonded to a photonics coupler structure 510 larger than PIC structure 500 such that both have rectangular optical bonding regions 181, 182, arranged in accordance with at least some implementations of the present disclosure. As shown, PIC structure 500 includes optical coupling layer 112 having optical bonding region 182 surrounded by hydrophobic structures 113 and photonics coupler structure 510 includes optical coupling layer 102 having optical bonding region 181 surrounded by hydrophobic structures 103. Hydrophobic structures 103, 113 may be any hydrophobic structures discussed herein, such as those discussed with respect to FIGS. 3E, 4A, 4B, 4C, and 4D. Hydrophobic structures 103, 113 may be the same or they may be different. In the example of FIG. 5A, photonics coupler structure 510 deploys optical substrate 101 having a larger area than PIC die 111. For example, optical substrate 101 may provide a fan out functionality, may provide surface area for other devices, or the like.

As shown, liquid droplet 123 is placed on optical bonding region 181 of optical coupling layer 102. Liquid droplet 123 may be any suitable liquid such as water of any suitable volume. Optical bonding regions 182, 181 are brought together by placement operation 124, which may be a pick and place of PIC die 111. As shown, liquid droplet 123 spreads out on optical bonding region 181 and is contained by hydrophobic structures 103. Although illustrated with PIC die 111 being placed on optical substrate 101, optical substrate 101 may be placed on PIC die 111 in some embodiments.

FIG. 5B is an illustration of plan views of PIC structure 500 and photonics coupler structure 510, arranged in accordance with at least some implementations of the present disclosure. As shown, optical bonding regions 181, 182 have substantially the same size and shape such that accurate bonding is attained using passive alignment as discussed herein. However, photonics coupler structure 510 and optical substrate 101 may be substantially larger in cross-sectional area than PIC structure 500 and PIC die 111, as discussed above. In some embodiments, photonics coupler structure 510 and optical substrate 101 have a lateral width W2 taken parallel to surface 104 of optical substrate 101 (i.e., in the x-y plane) that is greater than a lateral width L1 taken parallel to surface 114 of PIC die(i.e., in the x-y plane) and lateral length L2 taken parallel to surface 104 of optical substrate 101 (i.e., in the x-y plane) that is greater than a lateral length L1 taken parallel to surface 114 of PIC die(i.e., in the x-y plane). In some embodiments, one or both of lateral length L2 and lateral width W2 are not less than 25% larger than lateral length L1 and lateral width W1. In some embodiments, one or both of lateral length L2 and lateral width W2 are not less than 50% larger than lateral length L1 and lateral width W1. In some embodiments, one or both of lateral length L2 and lateral width W2 are not less than 100% larger than lateral length L1 and lateral width W1. Other sizes may be used. Although illustrated with respect to optical bonding regions 181, 182 being centered on optical substrate 101 and PIC die 111, optical bonding regions 181, 182 may be located in any suitable positions.

FIG. 5C is an illustration of a cross-sectional side view of a photonics structure 530 after bonding PIC structure 500 and photonics coupler structure 510, arranged in accordance with at least some implementations of the present disclosure. For example, photonics structure 530 is formed after evaporation of liquid droplet 123 and optional anneal processing. As shown, photonics structure 530 includes optical coupling layer 102 bonded to optical coupling layer 112 via bond 151 at interface 153. Photonics structure 530 includes one or more hydrophobic structures 103, 113 extending substantially around an outer perimeter 183 of optical bonding regions 181, 182 of optical coupling layers 102, 112 such that hydrophobic structures 103, 113 are each between surface 104 of optical substrate 101 and surface 114 of PIC die 111. As used herein, the term perimeter is used in its ordinary meaning to indicate an outer boundary of optical bonding regions 181, 182 in the x-y plane.

As discussed, optical coupling layers 102, 112 include optical features, photonics features, or the like that are to be accurately bonded. The optical features, photonics features, or the like may be dispersed in a bulk material layer. In some embodiments, the optical features, photonics features, or the like are waveguides, however any optical features, photonics features, or the like may be deployed. As shown in insert 539, in some embodiments, adjacent optical features 531, 532 are bonded to form composite optical features 536. In some embodiments, optical feature 531 is in optical coupling layer 102 and optical feature 532 is in optical coupling layer 112 with the discussed bonding seeking to perfectly align optical features 531, 532.

Each of optical feature 531, 532 may be a discrete feature or structure dispersed in a bulk material. In some embodiments, optical features 531, 532 are a first material such as silicon oxide (e.g., includes silicon and oxygen) or silicon nitride (e.g., includes silicon and nitrogen) and the bulk material is a second material such as silicon oxide, silicon nitride, silicon oxynitride (e.g., includes silicon, oxygen, and nitrogen), silicon-carbon-nitrogen composite (e.g., includes silicon, carbon and nitrogen), silicon carbide (e.g., includes silicon and carbon), or other dielectric material. In some embodiments, optical feature 531, 532 are silicon nitride, and the bulk material is silicon oxide, a silicon-carbon-nitrogen composite, or other dielectric material. In some embodiments, optical feature 531, 532 are silicon oxide, and the bulk material is silicon-carbon-nitrogen composite or other dielectric material.

With continued reference to insert 539, in some embodiments, adjacent optical features 531, 532 are bonded to form composite optical feature 536 such that composite optical feature 536 has a substantially aligned sidewalls 534. However, in other embodiments, adjacent optical features 531, 532 have a misalignment 535 during bond and form a composite optical feature 538 such that composite optical feature 538 has substantially misaligned sidewalls 537 and therefore composite optical feature 538 includes a jut or overhang. For example, the sidewall of composite optical feature 538 may have substantially vertical sidewall portions and a substantially horizontal sidewall portion. Similarly, as shown in insert 549, in some embodiments, adjacent hydrophobic structures 541, 542 form a composite hydrophobic structure 546 that has substantially aligned sidewalls 544. However, in other embodiments, adjacent hydrophobic structures 541, 542 have a misalignment 545 during bonding and form a composite hydrophobic structure 548 (e.g., any hydrophobic structure discussed herein) that has a substantially misaligned sidewall 547 and therefore hydrophobic structure 548 includes a jut or overhang at misaligned sidewall 547. For example, the sidewall of hydrophobic structure 548 may have substantially vertical sidewall portions and a substantially horizontal sidewall portion.

FIGS. 5A, 5B, and 5C illustrate hydrophobic features or structures 103, 113 that confine a single liquid droplet 123 to align optical coupling layers 102, 112 of photonics coupler structure 510 (e.g., an intermediate coupler) and PIC structure 500 with different dimensions (i.e., PIC die 111 of L1×W1 and optical substrate 101 of L2×W2 ). Discussion now turns to alternative bonding architectures.

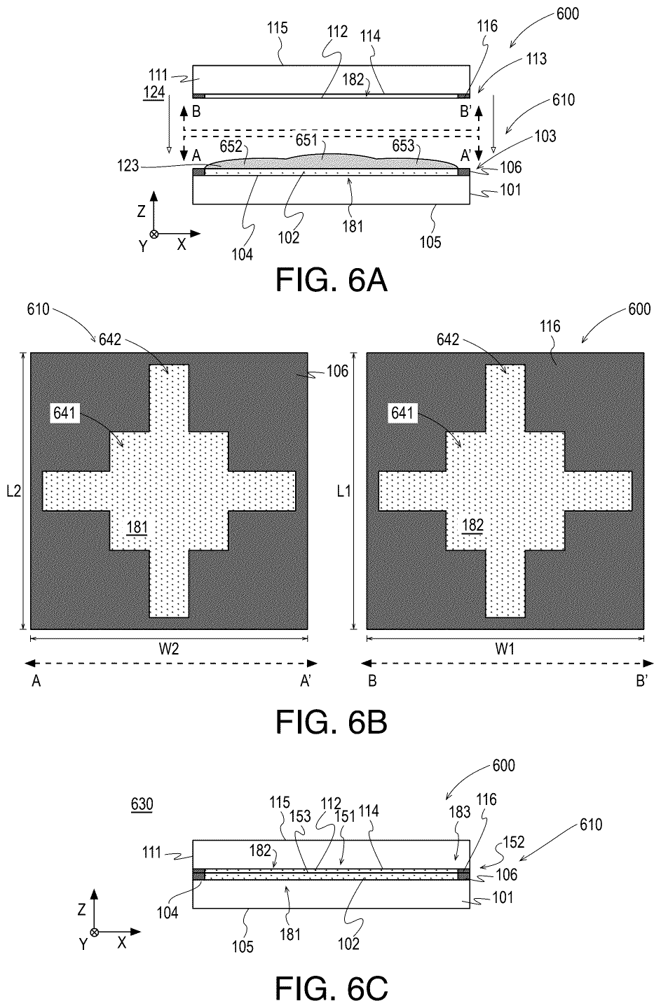

FIG. 6A is an illustration of a cross-sectional side view of a PIC structure 600 being bonded to a photonics coupler structure 610 of substantially the same size of PIC structure 600 such that both have square within cross optical bonding regions 181, 182, arranged in accordance with at least some implementations of the present disclosure. As shown, PIC structure 600 includes optical coupling layer 112 having optical bonding region 182 surrounded by hydrophobic structures 113 and photonics coupler structure 610 includes optical coupling layer 102 having optical bonding region 181 surrounded by hydrophobic structures 103. Hydrophobic structures 103, 113 may be any hydrophobic structures discussed herein. Hydrophobic structures 103, 113 may be the same or they may be different. In the example of FIG. 6A, photonics coupler structure 610 deploys optical substrate 101 having substantially the same size as that of PIC die 111. However, optical substrate 101 and PIC die 111 may have different sizes.

FIG. 6B is an illustration of plan views of PIC structure 600 and photonics coupler structure 610, arranged in accordance with at least some implementations of the present disclosure. As shown, optical bonding regions 181, 182 have substantially the same size and shape such that accurate bonding is attained using passive alignment as discussed herein. Furthermore, photonics coupler structure 610 and PIC structure 600 may have substantially the same cross-sectional areas such that lateral width W1 is the same or nearly the same as lateral width W2 and lateral length L1 is the same or nearly the same as lateral length L2.

In the example of FIGS. 6A, 6B, 6C, optical bonding regions 181, 182 each have a shape over surfaces 104, 114 as defined by hydrophobic features or structures 103, 113. As shown, more complex embodiments of the shapes of the areas of optical bonding regions 181, 182 may be deployed on optical substrate 101 and PIC die 111 to accommodate for surface design features and to improve. In some embodiments, the shape of optical bonding regions 181, 182 includes a central square 641 and rectangular segment 642 extending orthogonally from each side of central square 641. For example, the shape may be a square in cross shape having central square 641 coaxial with a cross defined by rectangular segments 642. Other shapes may be used.

With reference to FIG. 6A, liquid droplet 123 is placed on optical bonding region 181 of optical coupling layer 102 and liquid droplet 123 may include surface nodes 651, 652, 653 corresponding to the spread out of liquid droplet 123 over central square 641 (surface node 651) and rectangular segments 642 (surface nodes 652, 653). As discussed, optical bonding regions 182, 181 are brought together by placement operation 124. The shapes of optical bonding regions 181, 182 illustrated with respect to FIG. 6B may improve performance with respect to tilt between optical bonding regions 181, 182. For example, rectangular optical bonding regions 181, 182 may provide precise x-y alignment but, in some contexts, tilt relative the z-axis may be present. The shapes of optical bonding regions 181, 182 illustrated with respect to FIG. 6B may improve tilt performance.

FIG. 6C is an illustration of a cross-sectional side view of a photonics structure 630 after bonding PIC structure 600 and photonics coupler structure 610, arranged in accordance with at least some implementations of the present disclosure. For example, photonics structure 630 is formed after evaporation of liquid droplet 123 and optional anneal processing. Photonics structure 630 includes optical coupling layer 102 bonded to optical coupling layer 112 via bond 151 at interface 153. Photonics structure 630 includes one or more hydrophobic structures 103, 113 extending substantially around an outer perimeter 183 of optical bonding regions 181, 182 of optical coupling layers 102, 112 such that hydrophobic structures 103, 113 are each between surface 104 of optical substrate 101 and surface 114 of PIC die 111.

Optical coupling layers 102, 112 include optical features, photonics features, or the like such that bond 151 includes optical features, photonics features, or the like bonded across interface 153 as well as bulk or field material bonded across interface 153. As discussed, the optical features, photonics features, or the like may be waveguides or other optical couplers in some embodiments. Such bonded optical features, photonics features, or the like may have any characteristics discussed herein such as those discussed with respect to FIG. 5C.

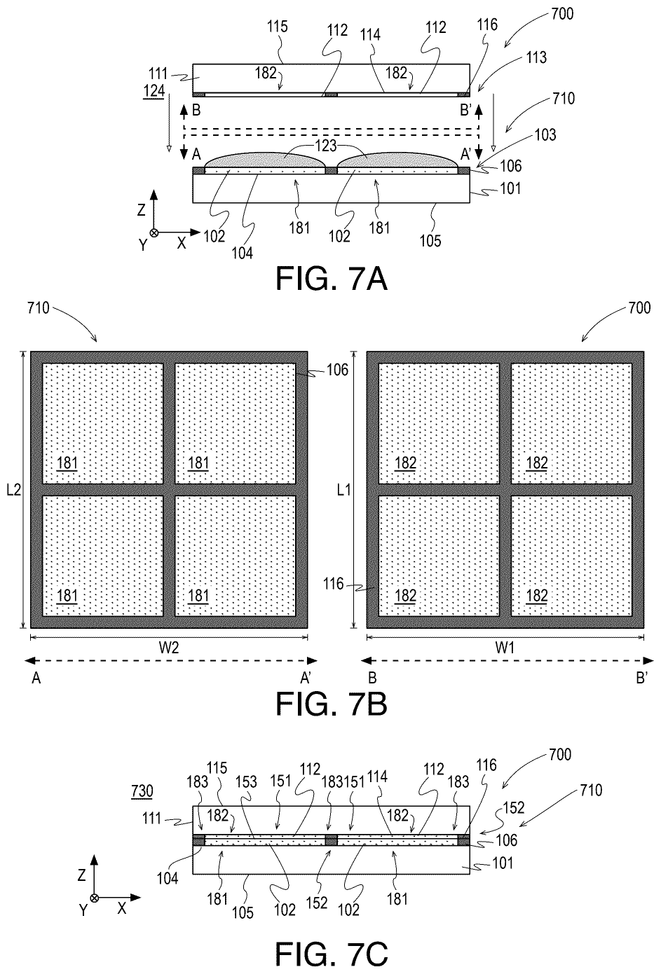

FIG. 7A is an illustration of a cross-sectional side view of a PIC structure 700 being bonded to a photonics coupler structure 710 of substantially the same size of PIC structure 700 such that both have multiple optical bonding regions 181, 182, arranged in accordance with at least some implementations of the present disclosure. As shown, PIC structure 700 includes multiple optical coupling layers 112 or the same optical coupling layer 112 having multiple optical bonding regions 182 each surrounded by hydrophobic structures 113. Similarly, photonics coupler structure 710 includes multiple optical coupling layers 102 or the same optical coupling layer 102 having multiple optical bonding regions 181 each surrounded by hydrophobic structures 103. Hydrophobic structures 103, 113 may be any hydrophobic structures discussed herein, and hydrophobic structures 103, 113 may be the same or they may be different. In the example of FIG. 7A, photonics coupler structure 710 deploys optical substrate 101 having substantially the same size as that of PIC die 111. However, optical substrate 101 and PIC die 111 may have different sizes.

Liquid droplet 123 is placed on each optical bonding region 181 and each of optical bonding regions 182, 181 are brought together by placement operation 124, which may be a pick and place of PIC die 111, for example. As shown, each of liquid droplets 123 spread out on optical bonding regions 181 and each is contained by hydrophobic structures 103. Although illustrated with PIC die 111 being placed on optical substrate 101, optical substrate 101 may be placed on PIC die 111 in some embodiments.

FIG. 7B is an illustration of plan views of PIC structure 700 and photonics coupler structure 710, arranged in accordance with at least some implementations of the present disclosure. As shown, photonics coupler structure 710 includes multiple optical bonding regions 181 each have substantially the same size and shape. In some embodiments, optical bonding regions 181 may have different sizes and/or shapes. Similarly, PIC structure 700 includes multiple optical bonding regions 182 that match optical bonding regions 181 of photonics coupler structure 710. Furthermore, photonics coupler structure 710 and PIC structure 700 may have substantially the same cross-sectional areas such that lateral width W1 is the same or nearly the same as lateral width W2 and lateral length L1 is the same or nearly the same as lateral length L2. However, photonics coupler structure 710 and PIC structure 700 may be differently sized in some embodiments.

FIG. 7C is an illustration of a cross-sectional side view of a photonics structure 730 after bonding PIC structure 700 and photonics coupler structure 710, arranged in accordance with at least some implementations of the present disclosure. For example, photonics structure 730 is formed after evaporation of liquid droplets 123 and optional anneal processing. Photonics structure 730 includes optical coupling layer(s) 102 bonded to optical coupling layer(s) 112 via bond(s) 151 at interface(s) 153. Photonics structure 730 includes one or more hydrophobic structures 103, 113 extending substantially around an outer perimeter 183 of each of corresponding ones of optical bonding regions 181, 182 of optical coupling layers 102, 112 such that hydrophobic structures 103, 113 are each between surface 104 of optical substrate 101 and surface 114 of PIC die 111.

As discussed, optical coupling layers 102, 112 include optical features, photonics features, or the like such that bond 151 includes optical features, photonics features, or the like bonded across interface 153 as well as bulk or field material bonded across interface 153. As discussed, the optical features, photonics features, or the like may be waveguides or other optical couplers in some embodiments. Such bonded optical features, photonics features, or the like may have any characteristics discussed herein such as those discussed with respect to FIG. 5C. In the embodiment of FIGS. 7A, 7B, 7C, multiple liquid droplets 123 are deployed that are individually confined between optical substrate 101 (e.g., the intermediate coupler) and PIC die 111. The advantage of this embodiment is that it increases the liquid surface area which may provide for higher capillary forces and improved alignment.

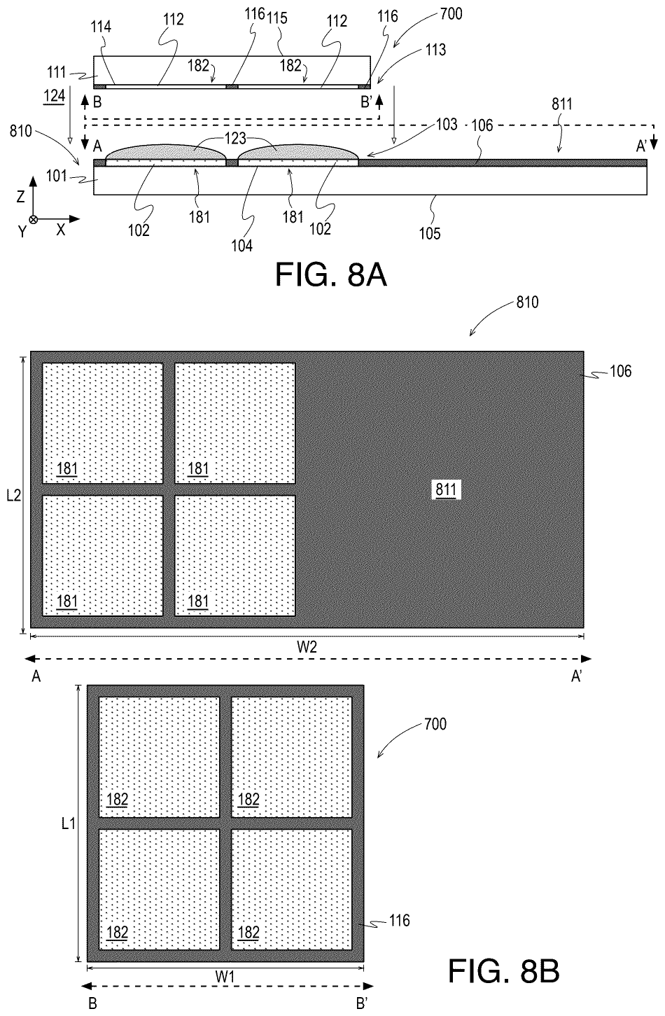

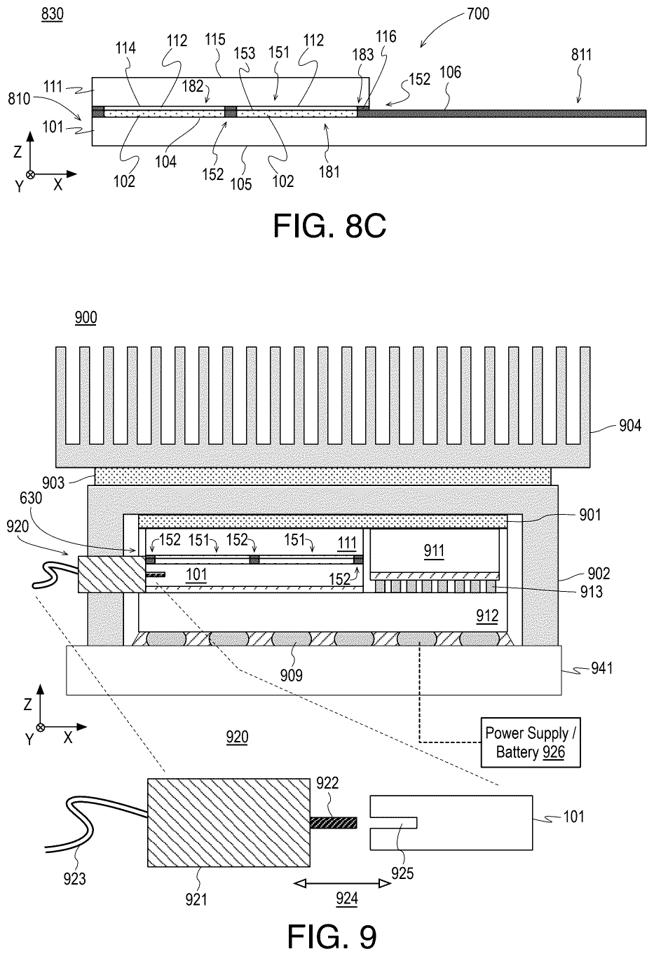

FIG. 8A is an illustration of a cross-sectional side view of PIC structure 700 being bonded to a photonics coupler structure 810 larger than PIC structure 700 and having a non-optical bonding region, arranged in accordance with at least some implementations of the present disclosure. As shown, PIC structure 700 includes multiple optical coupling layers 112 or the same optical coupling layer 112 having multiple optical bonding regions 182 each surrounded by hydrophobic structures 113. Similarly, photonics coupler structure 810 includes multiple optical coupling layers 102 or the same optical coupling layer 102 having multiple optical bonding regions 181 each surrounded by hydrophobic structures 103. In addition, photonics coupler structure 810 includes a non-optical bonding region 811, which may be covered in hydrophobic material 106 (as shown) or an exposed region of optical substrate 101. For example, optical substrate 101 may provide a region for coupling other devices such as electronic integrated circuit (EIC) dies, passive components (e.g., capacitors, resistors, etc.), or the like in non-optical bonding region 811. Hydrophobic structures 103, 113 may be any hydrophobic structures discussed herein, and hydrophobic structures 103, 113 may be the same or they may be different.

FIG. 8B is an illustration of plan views of PIC structure 700 and a photonics coupler structure 810, arranged in accordance with at least some implementations of the present disclosure. As shown, photonics coupler structure 810 includes multiple optical bonding regions 181 each have substantially the same size and shape. However, optical bonding regions 181 may have different sizes and/or shapes. Similarly, PIC structure 700 includes multiple optical bonding regions 182 that match optical bonding regions 181 of photonics coupler structure 810.

Furthermore, photonics coupler structure 810 includes non-optical bonding region 811. For example, photonics coupler structure 810 may be substantially larger than PIC structure 700 to accommodate other devices and/or due to other assembly architecture concerns. In some embodiments, lateral width W2 is not less than twice that of lateral width W1. In some embodiments, lateral width W2 is not less than twice that of lateral width W1 and lateral length L2 is substantially the same as that of lateral length L1. Other sizes may be used. Although illustrated with respect to PIC structure 700 attaching to photonics coupler structure 810 near an edge of photonics coupler structure 810, PIC structure 700 may be attached to photonics coupler structure 810 at any suitable position.

FIG. 8C is an illustration of a cross-sectional side view of a photonics structure 830 after bonding PIC structure 700 and photonics coupler structure 810, arranged in accordance with at least some implementations of the present disclosure. For example, photonics structure 830 is formed after evaporation of liquid droplets 123 and optional anneal processing. Photonics structure 830 includes optical coupling layer(s) 102 bonded to optical coupling layer(s) 112 via bond(s) 151 at interface(s) 153. Photonics structure 830 includes one or more hydrophobic structures 103, 113 extending substantially around an outer perimeter 183 of each of corresponding ones of optical bonding regions 181, 182 of optical coupling layers 102, 112 such that hydrophobic structures 103, 113 are each between surface 104 of optical substrate 101 and surface 114 of PIC die 111. As shown, attachment of PIC structure 700 leaves non-optical bonding region 811 exposed. Optical coupling layers 102, 112 include optical features, photonics features, or the like such that bond 151 includes optical features, photonics features, or the like bonded across interface 153 as well as bulk or field material bonded across interface 153 as discussed herein above. The embodiment of FIGS. 8A, 8B, and 8C provides for a design that may be deployed with the discussed self-assembly techniques to align photonics coupler structure 810 (e.g., an intermediate coupler) having significantly larger dimensions and aspect ratio with respect to PIC structure 700.

Returning to FIG. 2, methods 200 continues at operation 206, where the photonics integrated circuit structure is segmented (or diced) from the wafer or panel level bonding (if needed) using known dicing techniques, and where the resultant device (e.g., PIC structure) may be packaged, assembled, and implemented in any suitable form factor device such as a server implementation or other smaller form factor device.

FIG. 9 is an illustration of a cross-sectional side view of an assembly structure 900 similar to photonics structure 630 after attachment to an external optical fiber array connector, packaging with an electronic IC die, and deployment of heat removal solutions, arranged in accordance with at least some implementations of the present disclosure. As shown, photonics structure 630 is incorporated into assembly structure 900. Although illustrated with respect to photonics structure 630 of FIG. 6C and hydrophobic structures including sidewall spacers of hydrophobic material 451 as illustrated with respect to FIG. 4E, any photonics structure and hydrophobic structures discussed herein may be deployed in assembly structure 900. Assembly structure 900 further includes any number of electronic integrated circuit (EIC) dies 911 mounted to a substrate 912 via interconnects 913, which are optionally embedded in a mold or underfill material. Substrate 912 may be a package substrate, interposer, or board (such as a motherboard). Any number photonics structure 630 or other photonics structures having the same or different hydrophobic structures may be attached to substrate 912. As shown, substrate 912 may be coupled to a microelectronics board 941 by interconnects 909.

Optical substrate 101 may be coupled to an external optical fiber array connector 920 (e.g., an optical fiber connector or coupler). As shown in the enlarged view, external optical fiber array connector 920 may include a main body 921 and a pin 922 extending from main body 921. External optical fiber array connector 920 may be removably coupled 924 to optical substrate 101 by inserting/removing alignment pins 922 into an alignment hole 925 of optical substrate 101. In some embodiments, optical substrate 101 is an intermediate coupler that can be coupled to an external optical fiber array 923 using standard alignment pins 922 and pin holes 925.

Optical substrate 101 may include any number of holes 925 such as two alignment pin holes 925 to implement a receptacle to receive an external optical fiber array connector with mating alignment pins 922.

Assembly structure 900 further includes a battery/power supply 926 coupled to one or more of substrate 912 (i.e., a board, package substrate, or interposer), EIC dies 911, photonics structure 630, and/or other components of assembly structure 900. Power supply 926 may include a battery, voltage converter, power supply circuitry, or the like. Assembly structure 900 further includes a thermal interface material (TIM) 901 disposed on a top surface of EIC die 911 and, optionally, photonics structure 630. TIM 901 may include any suitable thermal interface material and may be characterized as TIM 1. Integrated heat spreader 902 having a surface on TIM 901 extends over EIC dies 911, photonics structure 630, and/or other components of assembly structure 900 and is mounted to substrate 912. Assembly structure 900 further includes a TIM 903 disposed on a top surface of integrated heat spreader 902. TIM 903 may include any suitable thermal interface material and may be characterized as TIM 2. TIM 901 and TIM 903 may be the same materials, or they may be different. A heat sink 904 (e.g., an exemplary heat dissipation device or thermal solution) is on TIM 903 and dissipates heat. Assembly structure 900 may be used in server form factors, for example.

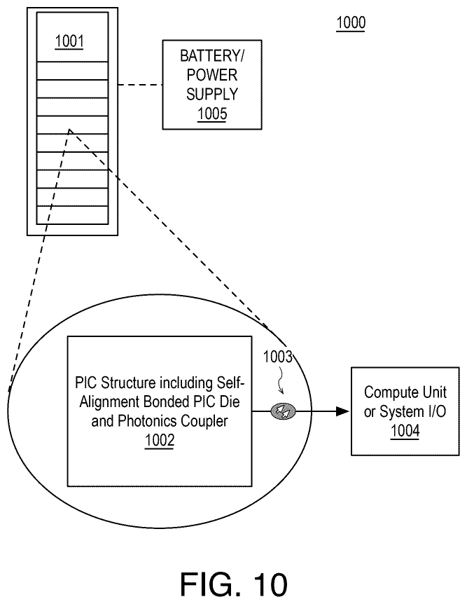

FIG. 10 illustrates an exemplary system 1000 employing a self-alignment bonded photonics integrated circuit and photonics coupler, arranged in accordance with at least some implementations of the present disclosure. For example, system 1000 may include a data server platform 1001 having a self-aligned bonded photonics integrated circuit and photonics coupler system 1002 as discussed elsewhere herein. As shown, data server platform 1001 may be powered in part by a battery/power supply 1005, which may include any suitable power supply circuitry. Although illustrated with respect to data server platform 1001, self-aligned bonded photonics integrated circuit and photonics coupler system 1002 may be deployed in any compute environment such as a desktop or mobile computing platform. Any photonics structure or assembly structure discussed herein may be deployed in self-aligned bonded photonics integrated circuit and photonics coupler system 1002.

Data server platform 1001 may be any commercial server, for example, including any number of high-performance computing platforms or compute units networked together for electronic data processing. As shown in the expanded view, self-aligned bonded photonics integrated circuit and photonics coupler system 1002 is optically coupled to an optical fiber 1003, which is in turn coupled to a compute unit or system I/O 1004. In some examples, the disclosed systems may include a sub-system such as a system on a chip (SOC) or an integrated system of multiple PIC and EICs.

Whether disposed within data server platform 1001 or other computing platform, system 1000 may further include memory circuitry and/or processor circuitry (e.g., RAM, a microprocessor, a multi-core microprocessor, graphics processor, etc.), a power management integrated circuit (PMIC), a controller, and a radio frequency integrated circuit (RFIC) (e.g., including a wideband RF transmitter and/or receiver (TX/RX)). Any of such components may be packaged, assembled and implemented, such that the package includes self-aligned bonded photonics integrated circuit and photonics coupler system 1002. In some embodiments, the RFIC includes a digital baseband and an analog front-end module further comprising a power amplifier on a transmit path and a low noise amplifier on a receive path). The RFIC may have an output coupled to an antenna (not shown) to implement any of a number of wireless standards or protocols, including but not limited to Wi-Fi (IEEE 802.11 family), WiMAX (IEEE 802.16 family), IEEE 802.20 , long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Functionally, the PMIC may perform battery power regulation, DC-to-DC conversion, etc., and so has an input coupled to battery/power supply 1005, and an output providing a current supply to other functional modules. Memory circuitry and/or processor circuitry may provide memory functionality, high level control, data processing and the like for system 1000.

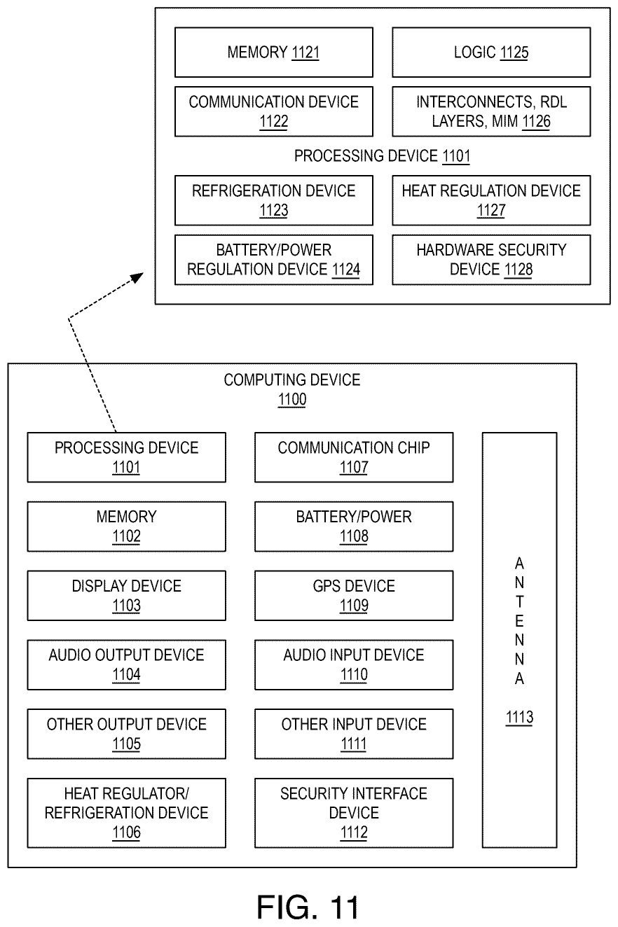

FIG. 11 is a block diagram of a computing device 1100, in accordance with some embodiments. For example, one or more components of computing device 1100 may include any of the PIC structures discussed elsewhere herein. A number of components are illustrated in FIG. 11, but any one or more of these components may be omitted or duplicated, as suitable for the application. In some embodiments, some of the components included in computing device 1100 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Any of such packaged components may include a self-aligned bonded photonics integrated circuit and photonics coupler system as discussed herein. Additionally, in various embodiments, computing device 1100 may not include one or more of the components illustrated in FIG. 11, but computing device 1100 may include interface circuitry for coupling to the one or more components. For example, computing device 1100 may not include a display device 1103, but may include display device interface circuitry (e.g., a connector and driver circuitry) to which display device 1103 may be coupled.

Computing device 1100 may include a processing device 1101 (e.g., one or more processing devices). As used herein, the term processing device or processor indicates a device that processes electronic data from registers and/or memory to transform that electronic data into other electronic data that may be stored in registers and/or memory. Processing device 1101 may include a memory 1121, a communication device 1122, a refrigeration/active cooling device 1123, a battery/power regulation device 1124, logic 1125, interconnects 1126 , a heat regulation device 1127, and a hardware security device 1128.

Processing device 1101 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable compute units.

Processing device 1101 may include a memory 1102, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 1101 shares a package with memory 1102. This memory may be used as cache memory and may include embedded dynamic random-access memory (eDRAM) or spin transfer torque magnetic random-access Memory (STT-M RAM).

Computing device 1100 may include a heat regulation/refrigeration device 1106. Heat regulation/refrigeration device 1106 may maintain processing device 1101 (and/or other components of computing device 1100) at a predetermined low temperature during operation. This predetermined low temperature may be any temperature discussed elsewhere herein.

In some embodiments, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium.

Computing device 1100 may include any photonics structure discussed herein that may facilitate communication between one or more instances of processing device 1101 and/or one or more instances of memory 1102, for example.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a global positioning system (GPS) device 1109 (or corresponding interface circuitry, as discussed above). GPS device 1109 may be in communication with a satellite-based system and may receive a location of computing device 1100, as known in the art.

Computing device 1100 may include another output device 1105 (or corresponding interface circuitry, as discussed above). Examples include an audio codec, a video codec, a printer, a wired or wireless transmitter for providing information to other devices, or an additional storage device.

Computing device 1100 may include another input device 1111 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, managing access lists, malware detection, or spyware detection.

Computing device 1100 may include an antenna 1113. Antenna 1113 may include any device that translates electrical current to radio waves and/or translates radio waves to electrical current.

Computing device 1100, or a subset of its components, may have any appropriate form factor, such as a server or other networked computing component, a mobile device, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a first optical coupling layer over a surface of a substrate, the first optical coupling layer within a region of the surface of the substrate, a second optical coupling layer over a surface of a photonics integrated circuit (PIC) die, the second optical coupling layer within a region of the surface of the PIC die, such that the first optical coupling layer is coupled to the second optical coupling layer, and at least one hydrophobic structure adjacent an outer perimeter of the first and second optical coupling layers, the hydrophobic structure between the surface of the substrate and the surface of the PIC die.

In one or more second embodiments, further to the first embodiments, the hydrophobic structure comprises a hydrophobic material, the hydrophobic material comprising one of a self-assembled monolayer material or a polymer film.

In one or more third embodiments, further to the first or second embodiments, the hydrophobic material extends from the surface of the substrate to the surface of the PIC die.

In one or more fourth embodiments, further to the first through third embodiments, the hydrophobic structure comprises a roughened surface of one of the first or second optical coupling layers or a trench in one of the first or second optical coupling layers.

In one or more fifth embodiments, further to the first through fourth embodiments, the apparatus further comprises a third optical coupling layer over the surface of the substrate, the third optical coupling layer within a second region of the surface of the substrate adjacent to the region of the surface of the substrate, and a fourth optical coupling layer over the surface of the PIC die, the fourth optical coupling layer within a second region of the surface of the PIC die, such that the third optical coupling layer is coupled to the fourth optical coupling layer, and such that the hydrophobic structure is between the first optical coupling layer and the third optical coupling layer.

In one or more sixth embodiments, further to the first through fifth embodiments, the substrate comprises a lateral width taken parallel to the surface of the substrate that is not less than 25% larger than a lateral width of the PIC die taken parallel to the surface of the PIC die.

In one or more seventh embodiments, further to the first through sixth embodiments, the surface of the substrate comprises a second region absent any optical coupling structures, the second region having an area not less than an area of the region of the surface of the substrate.

In one or more eighth embodiments, further to the first through seventh embodiments, the first optical coupling layer comprises one or more waveguides within a material layer, the material layer comprising silicon and one of oxygen, carbon, and nitrogen.

In one or more ninth embodiments, further to the first through eighth embodiments, the substrate comprises a layer of glass having a thickness of not less than 50 microns, a first length of not less than 10 mm and a second length orthogonal to the first length of not less than 10 mm, the apparatus further comprising an optical waveguide within the layer of glass, such that the optical waveguide extends substantially orthogonal to the thickness of the layer of glass.

In one or more tenth embodiments, further to the first through ninth embodiments, the first optical coupling layer comprises a shape over the surface of the substrate, the shape comprising a central square and a rectangular segment extending orthogonally from each side of the central square.

In one or more eleventh embodiments, further to the first through tenth embodiments, the apparatus further comprises a power supply coupled to the PIC die and/or an optical fiber array connecter coupled to the substrate.

In one or more twelfth embodiments, a system comprises a package including the first substrate, the PIC die, and the hydrophobic structures according to any of the apparatuses of the first through tenth embodiments, and a power supply and an optical fiber array connecter coupled to the coupled to package.

In one or more thirteenth embodiments, a first optical coupling layer over a surface of a substrate, the first optical coupling layer within a region of the surface of the substrate, a second optical coupling layer over a surface of a photonics integrated circuit (PIC) die, the second optical coupling layer within a region of the surface of the PIC die, such that the first optical coupling layer is coupled to the second optical coupling layer, and one or more structures extending substantially around an outer perimeter of the first and second optical coupling layers such that the one or more structures comprise a layer of material having an atomic composition of at least ten percent carbon or at least ten percent fluorine.

In one or more fourteenth embodiments, further to the thirteenth embodiments, the layer of material comprises a layer of hydrophobic material.

In one or more fifteenth embodiments, further to the thirteenth or fourteenth embodiments, the layer of material extends from the surface of the substrate to the surface of the PIC die.

In one or more sixteenth embodiments, further to the thirteenth through fifteenth embodiments, the one or more structures are on a roughened surface of one of the first or second optical coupling layers or a trench in one of the first or second optical coupling layers.

In one or more seventeenth embodiments, further to the thirteenth through sixteenth embodiments, the apparatus further comprises a power supply coupled to the PIC die and/or an optical fiber array connecter coupled to the substrate.

In one or more eighteenth embodiments, a system comprises a package including the first substrate, PIC die, and the structures according to any of the apparatuses of the thirteenth through sixteenth embodiments, and a power supply and an optical fiber array connecter coupled to the coupled to package.

In one or more nineteenth embodiments, a method comprises depositing a liquid droplet on one of a first optical coupling layer of a substrate, the first optical coupling layer surrounded by first hydrophobic structures, or a second optical coupling layer of a photonics integrated circuit (PIC) die, the second optical coupling layer surrounded by second hydrophobic structures, contacting the other of the first optical coupling layer and the second optical coupling layer to the liquid droplet, and evaporating the liquid droplet to bond the first optical coupling layer and the second optical coupling layer.

In one or more twentieth embodiments, further to the nineteenth embodiments, the method further comprises forming one of the first hydrophobic structures or the second hydrophobic structures by depositing a sacrificial layer on one of the first optical coupling layer or the second optical coupling layer, forming a layer of hydrophobic material comprising a first portion on the sacrificial layer and second portion on at least a sidewall of the one of the first optical coupling layer or the second optical coupling layer, and removing the first portion of the layer of the hydrophobic material and the sacrificial layer.

In one or more twenty-first embodiments, further to the nineteenth or twentieth embodiments, the method further comprises patterning, prior to removing the first portion of the layer of the hydrophobic material and the sacrificial layer, the one of the first optical coupling layer or the second optical coupling layer and the sacrificial layer.

In one or more twenty-second embodiments, further to the nineteenth through twenty-first embodiments, the liquid droplet is deposited on the substrate, the substrate comprising a layer of glass having a thickness of not less than 50 microns, a first length of not less than 10 mm and a second length orthogonal to the first length of not less than 10 mm.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a first optical coupling layer over a surface of a substrate, the first optical coupling layer within a region of the surface of the substrate;
a second optical coupling layer over a surface of a photonics integrated circuit (PIC) die, the second optical coupling layer within a region of the surface of the PIC die, wherein the first optical coupling layer is coupled to the second optical coupling layer; and
at least one hydrophobic structure adjacent an outer perimeter of the first and second optical coupling layers, the hydrophobic structure between the surface of the substrate and the surface of the PIC die.

2. The apparatus of claim 1, wherein the hydrophobic structure comprises a hydrophobic material, the hydrophobic material comprising one of a self-assembled monolayer material or a polymer film.

3. The apparatus of claim 2, wherein the hydrophobic material extends from the surface of the substrate to the surface of the PIC die.

4. The apparatus of claim 1, wherein the hydrophobic structure comprises a roughened surface of one of the first or second optical coupling layers or a trench in one of the first or second optical coupling layers.

5. The apparatus of claim 1, further comprising:
a third optical coupling layer over the surface of the substrate, the third optical coupling layer within a second region of the surface of the substrate adjacent to the region of the surface of the substrate; and
a fourth optical coupling layer over the surface of the PIC die, the fourth optical coupling layer within a second region of the surface of the PIC die, wherein the third optical coupling layer is coupled to the fourth optical coupling layer, and wherein the hydrophobic structure is between the first optical coupling layer and the third optical coupling layer.

6. The apparatus of claim 1, wherein the substrate comprises a lateral width taken parallel to the surface of the substrate that is not less than 25% larger than a lateral width of the PIC die taken parallel to the surface of the PIC die.

7. The apparatus of claim 1, wherein the surface of the substrate comprises a second region absent any optical coupling structures, the second region having an area not less than an area of the region of the surface of the substrate.

8. The apparatus of claim 1, wherein the first optical coupling layer comprises one or more waveguides within a material layer, the material layer comprising silicon and one of oxygen, carbon, and nitrogen.

9. The apparatus of claim 1, wherein the substrate comprises a layer of glass having a thickness of not less than 50 microns, a first length of not less than 10 mm and a second length orthogonal to the first length of not less than 10 mm, the apparatus further comprising an optical waveguide within the layer of glass, wherein the optical waveguide extends substantially orthogonal to the thickness of the layer of glass.

10. The apparatus of claim 1 wherein the first optical coupling layer comprises a shape over the surface of the substrate, the shape comprising a central square and a rectangular segment extending orthogonally from each side of the central square.

11. The apparatus of claim 1, further comprising a power supply coupled to the PIC die and/or an optical fiber array connecter coupled to the substrate.

12. An apparatus, comprising:
a first optical coupling layer over a surface of a substrate, the first optical coupling layer within a region of the surface of the substrate;
a second optical coupling layer over a surface of a photonics integrated circuit (PIC) die, the second optical coupling layer within a region of the surface of the PIC die, wherein the first optical coupling layer is coupled to the second optical coupling layer; and
one or more structures extending substantially around an outer perimeter of the first and second optical coupling layers wherein the one or more structures comprise a layer of material having an atomic composition of at least ten percent carbon or at least ten percent fluorine.

13. The apparatus of claim 12, wherein the layer of material comprises a layer of hydrophobic material.

14. The apparatus of claim 12, wherein the layer of material extends from the surface of the substrate to the surface of the PIC die.

15. The apparatus of claim 12, wherein the one or more structures are on a roughened surface of one of the first or second optical coupling layers or a trench in one of the first or second optical coupling layers.

16. The apparatus of claim 12, further comprising a power supply coupled to the PIC die and/or an optical fiber array connecter coupled to the substrate.

17. A method, comprising:
depositing a liquid droplet on one of a first optical coupling layer of a substrate, the first optical coupling layer surrounded by first hydrophobic structures, or a second optical coupling layer of a photonics integrated circuit (PIC) die, the second optical coupling layer surrounded by second hydrophobic structures;
contacting the other of the first optical coupling layer and the second optical coupling layer to the liquid droplet; and
evaporating the liquid droplet to bond the first optical coupling layer and the second optical coupling layer.

18. The method of claim 17, further comprising forming one of the first hydrophobic structures or the second hydrophobic structures by:
depositing a sacrificial layer on one of the first optical coupling layer or the second optical coupling layer;
forming a layer of hydrophobic material comprising a first portion on the sacrificial layer and second portion on at least a sidewall of the one of the first optical coupling layer or the second optical coupling layer; and
removing the first portion of the layer of the hydrophobic material and the sacrificial layer.

19. The method of claim 18, further comprising:
patterning, prior to removing the first portion of the layer of the hydrophobic material and the sacrificial layer, the one of the first optical coupling layer or the second optical coupling layer and the sacrificial layer.

20. The method of claim 17, wherein the liquid droplet is deposited on the substrate, the substrate comprising a layer of glass having a thickness of not less than 50 microns, a first length of not less than 10 mm and a second length orthogonal to the first length of not less than 10 mm.
